(19) United States
(12) Patent Application Publication
(10) Pub. No.: US 2026/0045672 A1
(43) Pub. Date: Feb. 12, 2026

(54) QUANTUM CHIP PARAMETER DETERMINATION METHOD AND DEVICE, FILTERING REGULATION METHOD AND DEVICE

(71) Applicant: YANGTZE DELTA INDUSTRIAL INNOVATION CENTER OF QUANTUM SCIENCE AND TECHNOLOGY, Suzhou (CN)

(72) Inventors: Weigui GUO, Suzhou (CN); Xiang ZHANG, Suzhou (CN); Bin YANG, Suzhou (CN); Xuefei LIU, Suzhou (CN)

(21) Appl. No.: 19/366,560

(22) Filed: Oct. 23, 2025

Related U.S. Application Data
(63) Continuation of application No. PCT/CN2024/131411, filed on Nov. 11, 2024.

(30) Foreign Application Priority Data
Dec. 20, 2023 (CN) 202311759914.1

(51) Int. Cl. H01P 1/212; G06N 10/70; H01P 7/08; H03H 11/04

(52) U.S. Cl. CPC H01P 1/212; G06N 10/70; H01P 7/086; H03H 11/0405

(57) ABSTRACT

The disclosure provides a quantum chip parameter determination method and device, and a filtering regulation method and device, relates to the field of quantum chips, to address the problem that a large amount of space in quantum chips are occupied in order to meet the filtering function of the quantum chips having a large number of qubits; wherein Josephson junctions are provided on the coplanar waveguide of the filter, and adjusting the critical current of the Josephson junctions and changing the equivalent inductances corresponding to the filter enables regulating the center frequency of the filter; the initial length that meets the center frequency range and bandwidth range, as well as the inductance set are selected, so that the Josephson junctions can, during regulation, cover the frequencies required by all resonant cavities, encompassing all resonant cavity frequency bands through one filter.

### CROSS-REFERENCE TO RELATED APPLICATIONS

The application is a continuation of International Application No. PCT/CN2024/131411, with an international filing date of Nov. 11, 2024, which is based upon and claims priority to Chinese Patent Application No. 202311759914.1, filed on Dec. 20, 2023, the entire contents of all of which are incorporated herein by reference.

### TECHNICAL FIELD

The disclosure relates to the field of quantum chip technology, particularly to a quantum chip parameter determination method and device, a filtering regulation method and device.

### BACKGROUND

The development of quantum computers has reached a stage where their computational power surpasses that of classical computers for certain specific problems. However, because the error rate of individual qubits remains suboptimal hundreds of physical qubits are required for fault-tolerant calculation to achieve the function of one qubit. Thus, the total number of qubits needed significantly increases. Considering the large number of qubits and their typically short coherence times, it is particularly important to read out qubit states quickly and with high fidelity-without further reducing their lifetimes. In superconducting quantum circuits, measuring the state of resonator coupled to a qubit can be used to infer the qubit's state. This indirect measurement technique enables quantum non-demolition measurement, which greatly reduces the measurement-induced disturbance to the qubit. However, qubits still lose energy through this additional measurement channel, thereby shortening their lifetimes.

Incorporating a filtering circuit into the measurement chain can suppress this energy leakage without affecting the coupling between the resonator and the external readout circuitry. Thus, it is possible to achieve fast readout of qubit states while maintaining longer qubit lifetimes. Therefore, integrating filtering circuits into superconducting quantum circuits is an effective way to enhance quantum chip performance. Due to the large number of qubits, dedicating one filter per qubit would incur significant spatial overhead. To save space, it is a common practice to have multiple qubits share a bandpass filter. However, when multiple qubits share a filter, frequency crosstalk between the resonators becomes more pronounced. The coverage range of resonant cavity frequency cannot be too small for reducing the crosstalk of resonant cavity frequency. If the fabricated filter has a frequency band offset or fails to cover the entire required frequency range, the filtering effect for some qubits can be poor—or the filter cannot function at all for those qubits.

Obviously, how to execute effective filtering for a large number of qubits on a quantum chip without occupying excessive space is an urgent technical problem that needs to be addressed by those skilled in the art.

### SUMMARY

The disclosure provides a quantum chip parameter determination method and device, and a filtering regulation method and device. The problem that a large amount of space in quantum chips are occupied in order to meet the filtering function of the quantum chips having a large number of qubits is solved.

To address the aforementioned technical problems, the disclosure provides a quantum chip parameter determination method, wherein the quantum chip includes: a filter; the filter includes a coplanar waveguide, at least one pair of parallel Josephson junctions, and an input coupling capacitor; the coplanar waveguide is coupled to the readout line; the Josephson junctions are disposed on the coplanar waveguide; the input coupling capacitor is disposed at the input end of coplanar waveguide;
the method includes:
determining the center frequency range and bandwidth range corresponding to filtering
based on multiple resonant cavities coupled to the readout line;
acquiring the initial length from the input end to the output end of coplanar waveguide, and the initial inductance set which is a set of preset equivalent inductances of the Josephson junctions;
determining whether there are inductance values in the initial inductance set that meet both the center frequency range and the bandwidth range, based on the initial length;
and if any, outputting the selected inductance set;
and if no, adjusting the initial length until there are inductance values in the initial inductance set that meet both the center frequency range and the bandwidth range; and
determining the area of the Josephson junctions based on the selected inductance set, and determining the length from the input end to the output end of the coplanar waveguide based on the current initial length.

Optionally, in the aforementioned quantum chip parameter determination method, determining whether there are inductance values in the initial inductance set that meet both the center frequency range and the bandwidth range based on the initial length includes:
determining whether there are inductance values in the initial inductance set that meet the center frequency range based on the initial length;
if any, acquiring the corresponding filtering bandwidth data set based on the inductance value set that meets the center frequency range;
determining whether the filtering bandwidth data set meets the bandwidth range;
if meeting, it is determined that there are inductance values in the initial inductance set that meet both the center frequency range and the bandwidth range; and
if no or not meeting, it is determined that there are no inductance values in the initial inductance set that meet both the center frequency range and the bandwidth range.

Optionally, in the aforementioned quantum chip parameter determination method, acquiring the corresponding filtering bandwidth data set based on the inductance value set that meets the center frequency range includes:
acquiring the corresponding filtering quality factor data set based on the inductance value set that meets the center frequency range; and
acquiring the corresponding filtering bandwidth data set based on the filtering quality factor data set.

Optionally, in the aforementioned quantum chip parameter determination method, the coplanar waveguide includes a first coplanar waveguide segment and a second coplanar waveguide segment;
the first coplanar waveguide segment is a segment from the input end to the output end of the coplanar waveguide; the second coplanar waveguide segment is a segment from the output end to the ground end of the coplanar waveguide; and
the Josephson junctions are disposed at the intersection of the first coplanar waveguide segment and the second coplanar waveguide segment.

Optionally, in the aforementioned quantum chip parameter determination method, the filter further includes an output coupling capacitor; and the output coupling capacitor is disposed at the output end of the readout line.

To address the aforementioned problems, the disclosure also provides a filtering regulation method for quantum chip, applied to the quantum chips prepared based on the aforementioned quantum chip parameter determination method;
the method includes:
scanning the current control terminal of the Josephson junctions with different bias currents to acquire the ratio curve of the output signal to the input signal of the readout line;
determining a bias current corresponding to each resonant cavity based on the ratio curve, as the working current corresponding to each resonant cavity; and
reading the corresponding state of each resonant cavity under the working current.

Optionally, in the aforementioned filtering regulation method for quantum chips, scanning the current control terminal of the Josephson junctions with different bias currents to acquire the ratio curve of the output signal to the input signal of the readout line includes:
scanning the current control terminal of the Josephson junctions with a bias current at a first preset current interval, acquiring a first curve of the output signal and input signal of the readout line;
determining the target center frequency and bandwidth of each resonant cavity, that is, the corresponding current bias range, based on the first curve;
scanning the current control terminal of the Josephson junctions within the current bias range with a bias current at a second preset current interval, acquiring a second curve of the output signal and input signal of the readout line; and taking the second curve as the ratio curve.

Optionally, in the aforementioned filtering regulation method for quantum chips, scanning the current control terminal of the Josephson junctions with the bias current at the first preset current interval includes:
scanning the current control terminal of the Josephson junctions with the bias current at the first preset current interval during an oscillation period of the Josephson junctions.

To address the aforementioned problems, the disclosure also provides a quantum chip parameter determination device, the quantum chip includes: a filter; the filter includes a coplanar waveguide, at least one pair of parallel Josephson junctions, and an input coupling capacitor; the coplanar waveguide is coupled to the readout line; the Josephson junctions are disposed on the coplanar waveguide; the input coupling capacitor is disposed at the input end of coplanar waveguide;
the device includes:
an adjustment range determination module that is used to determine the center frequency range and bandwidth range of the corresponding to filtering based on multiple resonant cavities coupled to the readout line;
an initial data acquisition module that is used to acquire the initial length from the input end to the output end of the coplanar waveguide, and the initial inductance set which is a set of preset equivalent inductances of the Josephson junctions;
a judgment module that is used to determine whether there are inductance values in the initial inductance set that meet both the center frequency range and the bandwidth range based on the initial length; if any, trigger a result output module; if no, trigger an adjustment module; a result output module that is used to output the selected inductance set;
an adjustment module that is used to adjust the initial length until there are inductance values in the initial inductance set that meet both the center frequency range and the bandwidth range; and
a parameter determination module that is used to determine the area of the Josephson junctions based on the selected inductance set, and determine the length from the input end to the output end of the coplanar waveguide based on the current initial length.

To address the aforementioned problems, the disclosure further provides a filtering regulation device for quantum chip, applied to the quantum chips prepared based on the aforementioned quantum chip parameter determination method;
the device includes:
a scanning module that is used to scan the current control terminal of the Josephson junctions with different bias currents, and to acquire the ratio curve of the output signal and input signal of the readout line;
an analysis module that is used to determine the bias current corresponding to each resonant cavity based on the ratio curve, as the working current corresponding to each resonant cavity; and
a reading module that is used to read the state of each corresponding resonant cavity under the working current.

The disclosure provides a quantum chip parameter determination method. The quantum chip includes a filter. The filter includes a coplanar waveguide, at least one pair of parallel Josephson junctions, and an input coupling capacitor. The coplanar waveguide is coupled to the readout line. The Josephson junctions are disposed on a coplanar waveguide. The input coupling capacitor is disposed at the input end of coplanar waveguide. Determine the center frequency range and bandwidth range of the corresponding to filtering based on multiple resonant cavities coupled to the readout line. Acquire the initial length from the input end to the output end of coplanar waveguide, and the initial inductance set. The initial inductance set is a set of preset equivalent inductances of the Josephson junctions. Determine whether there are inductance values in the initial inductance set that meet both the center frequency range and the bandwidth range, based on the initial length. If any, output the selected inductance set. If no, adjust the initial length until there are inductance values in the initial inductance set that meet both the center frequency range and the bandwidth range. Determine the area of the Josephson junctions based on the selected inductance set. Determine the length from the input end to the output end of the coplanar waveguide based on the current initial length. Josephson junctions are provided on the coplanar waveguide of the filter provided in the disclosure. By adjusting the critical current of the Josephson junctions and changing the equivalent inductances corresponding to the filter, the center frequency of the filter can be regulated. The initial length that meets the center frequency range and bandwidth range, as well as the inductance set are selected. So that the Josephson junctions can, during regulation, cover the frequencies required by all resonant cavities, encompassing all resonant cavity frequency bands through one filter. During use, the bandwidth and center frequency of the filter can be regulated by adjusting the critical current of the Josephson junctions to achieve better filtering effect.

In addition, the disclosure also provides a quantum chip parameter determination device, corresponding to the aforementioned quantum chip parameter determination method, with the same effect as above.

The filtering regulation method for quantum chips provided in the disclosure is applied to the quantum chips prepared based on the aforementioned quantum chip parameter determination method. Scan the current control terminal of the Josephson junctions with different bias currents to acquire the ratio curve of the output signal to the input signal of the readout line. Determine a bias current corresponding to each resonant cavity based on the ratio curve, as the working current corresponding to each resonant cavity. Read the corresponding state of each resonant cavity under the working current. The working current of each resonant cavity is obtained by scanning. When reading is required, the working current of the Josephson junctions is adjusted to enable the filter operate at the corresponding center frequency and bandwidth range. Since the filter's center frequency is adjustable, the filter can be designed with a narrow bandwidth to improve the filtering effect, while not losing the frequency range of filtering. And multiple resonant cavities share one filter, significantly saving the space required by the filtering circuit, so that the filter can be integrated on a quantum chip having a large number of qubits.

In addition, the disclosure also provides a filtering regulation device for quantum chip, corresponding to the aforementioned filtering regulation method for the quantum chip, with the same effect as above.

### BRIEF DESCRIPTION OF THE DRAWINGS

In order to more clearly illustrate the technical solution of the embodiments of the disclosure, a brief introduction can be given to the accompanying drawings required for the description of the embodiments. Obviously, the accompanying drawings described below are some embodiments of the disclosure. Those of ordinary skill in the art can obtain other drawings based on these drawings without creative work.

FIG. 1 is a flowchart of a quantum chip parameter determination method provided in an embodiment of the disclosure;

FIG. 2 is a schematic diagram of a conventional quantum chip;

FIG. 3 is a schematic diagram of a quantum chip provided in an embodiment of the disclosure;

FIG. 4 is a schematic diagram of another quantum chip provided in an embodiment of the disclosure;

FIG. 5 is an equivalent circuit diagram of a quantum chip provided in an embodiment of the disclosure;

FIG. 6 is a flowchart of a quantum chip filtering regulation method provided in an embodiment of the disclosure;

FIG. 7 is a structural diagram of a quantum chip parameter determination device provided in an embodiment of the disclosure;

FIG. 8 is a structural diagram of a quantum chip filtering regulation device provided in an embodiment of the disclosure.

### DETAILED DESCRIPTION OF THE EMBODIMENTS

The technical solutions in the embodiments of the disclosure can be described clearly and completely in conjunction with the accompanying drawings of the embodiments of the disclosure. Obviously, the described embodiments are only a part of the embodiments of the disclosure, rather than all the embodiments. Based on the embodiments of the disclosure, all other embodiments obtained by those of ordinary skill in the art without creative work shall fall within the protection scope of the disclosure.

The core of the disclosure is to provide a quantum chip parameter determination method and device, as well as a filtering regulation method and device.

In order to enable persons skilled in the art to better understand the disclosure scheme, the disclosure can be further elaborated in detail below in conjunction with the accompanying drawings and specific embodiments.

In superconducting quantum circuits, directly measuring the state of qubits can cause the rapid dissipation of qubit energy to the outside world, resulting in the destruction of qubit state. A common solution is to indirectly determine the state of qubit by measuring the state of resonant cavities coupled to the qubit. Specifically, since the qubit is usually in a strongly coupled state with the resonant cavities, the state of the qubit can be determined by measuring the frequency shift of resonant cavities. Thus, direct manipulation of the qubit is avoided and non-destructive measurement of the qubit is achieved.

Due to the large number of qubits, if each qubit is provided with a filter, the space overhead on the quantum chip can be very high. To save space, it is a common practice for several qubits to share a bandpass filter. Using multiple resonant cavities with the same frequency as a filter can improve the filtering effect. However, the large space occupied by a single resonant cavity can greatly increase the space occupied by the filter on the chip, further compressing the space left for qubits. In addition, when multiple qubits share a filter, the resonant cavities between different qubits can have more pronounced frequency crosstalk. A common approach is to separate the resonant cavity frequencies corresponding to different qubits as much as possible to reduce crosstalk. But in this case a bandpass filter with a larger bandwidth has to be used so that the frequency range that can pass through the bandpass filter can cover the intrinsic frequencies of all qubit corresponding resonant cavities. This greatly reduces the filtering effect on individual qubits, especially for resonant cavities with frequencies far from the center frequency of the bandpass filter.

The filter needs to be integrated on a quantum chip, and several resonant cavities corresponding to a few qubits share the same filter. And reducing the frequency crosstalk of resonant cavities requires a not too small frequency coverage range of resonant cavities. If the processed filter has offset in the working frequency band and cannot cover the required frequency range, the filtering effect on some qubits can be poor, and can even be outside the working frequency band of the bandpass filter.

Therefore, it is necessary to provide a filter that can cover all resonant cavity frequency bands and have a narrow bandwidth and non-offset center frequency, and the embodiment provides a quantum chip parameter determination method. The quantum chip includes: a filter. The filter includes a coplanar waveguide, at least one pair of parallel Josephson junctions, and an input coupling capacitor. The coplanar waveguide is coupled to the readout line. The Josephson junctions are disposed on a coplanar waveguide. The input coupling capacitor is disposed at the input end of coplanar waveguide;

Referring to FIG. 1, the method includes:
S11: Determine the center frequency range and bandwidth range of the corresponding to filtering based on multiple resonant cavities coupled to the readout line;
S12: Acquire the initial length from the input end to the output end of coplanar waveguide. The initial inductance set is a set of preset equivalent inductances of the Josephson junctions;
S13: Determine whether there are inductance values in the initial inductance set that meet both the center frequency range and the bandwidth range, based on the initial length;
S14: And if any, output the selected inductance set;
S15: And if no, adjust the initial length until there are inductance values in the initial inductance set that meet both the center frequency range and the bandwidth range; and
S16: Determine the area of the Josephson junctions based on the selected inductance set. Determine the length from the input end to the output end of the coplanar waveguide based on the current initial length.

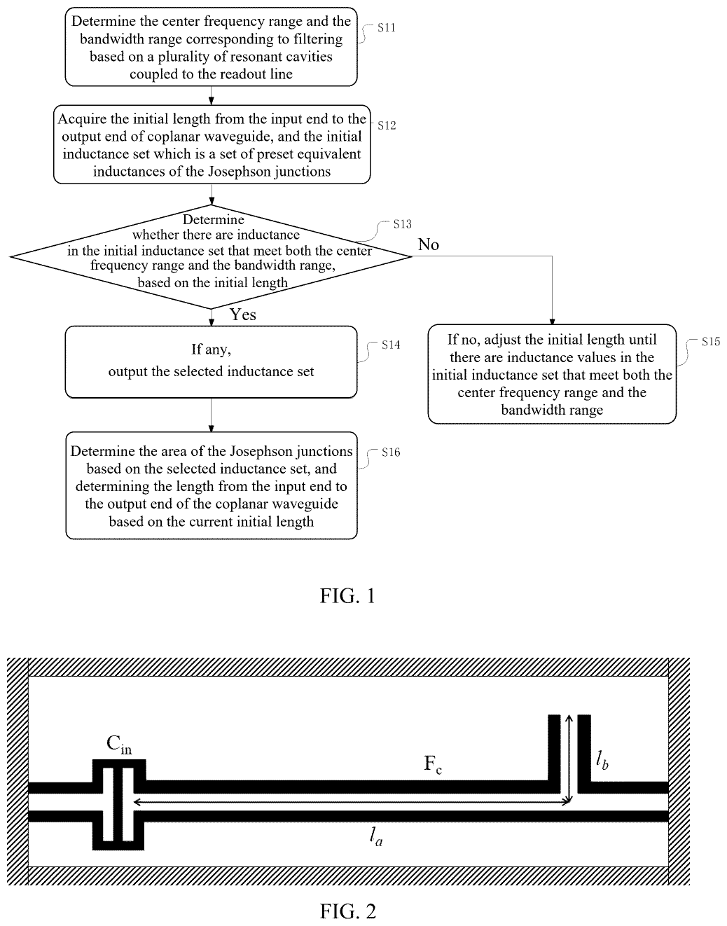

The common implementation of filters is based on the coplanar waveguides with λ/2 or λ/4 wavelength. The embodiment takes a filter based on a coplanar waveguide with λ/4 wavelength as an example. FIG. 2, a schematic diagram of a common quantum chip, shows a filter based on a coplanar waveguide with λ/4 wavelength. The filter's bandwidth can also be regulated by adjusting the value of input capacitor Cin. Considering the lumped element model, the filter's quality factor can be simplified as:

$${Q}_{F} = \frac{π}{4 {sin ( \frac{π x}{2 l} )}^{2}} \approx \frac{{l}^{2}}{π {{l}_{b}}^{2}} ;$$

Q_{F} is the quality factor. l_{b} is the distance from the output end to the ground end of the filter coplanar waveguide. l=lₐ+l_{b} is the total length of coplanar waveguide of filter. lₐ is the distance from the input end to the output end of coplanar waveguide of the filter. The external quality factor and dissipation rate of the filter satisfy: γ=ω_{F}/Q_{F}. ω_{F} represents the passband frequency of the filter, which can be used to characterize the filter's bandwidth size. Therefore the filter's bandwidth is also related to the size of lb. As l_{b} increases, the voltage at the output of the filter gradually rises, and the corresponding bandwidth also gradually increases. If a filter based on a λ/2 wavelength resonant cavity is used, merely an output coupling capacitor should be added to the right side of the coplanar waveguide of the filter.

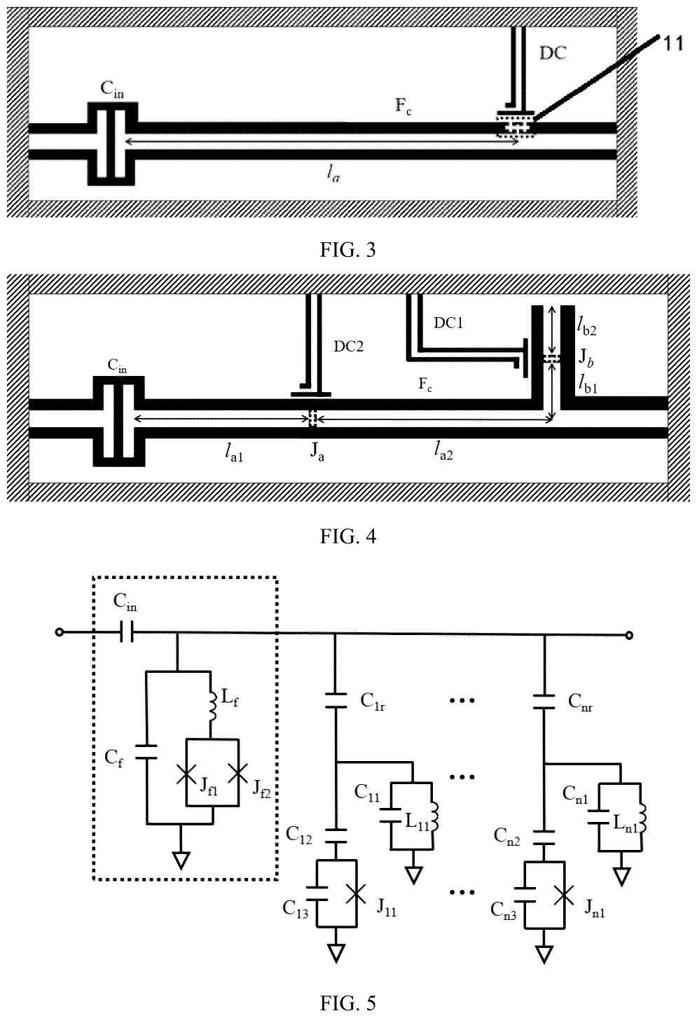

FIG. 3 is a schematic diagram of a quantum chip provided in an embodiment of the disclosure. Referring to FIG. 3, Cin is the input coupling capacitor. The dashed part is parallel Josephson junctions 11. The control terminal of Josephson junctions 11 is represented by the DC terminal. F_{c} is the coplanar waveguide part of filter. And l_{b} represents the distance from the input end to the output end of the coplanar waveguide. The filter's output coupling capacitor or the l_{b} part from the output terminal to the ground terminal of coplanar waveguide is replaced with parallel grounded Josephson junctions. DC, the end-grounded coplanar waveguide, provides a DC current bias and can provide a local magnetic field inside the parallel Josephson junctions. Thus, the critical current of the Josephson junctions and the filter's corresponding equivalent inductances are changed, and the filter's center frequency is adjusted.

FIG. 4 is a schematic diagram of another quantum chip provided in an embodiment of the disclosure. Referring to FIG. 4, lₐ is divided into two parts, lₐ₁ and lₐ₂, by two parallel Josephson junctions Jₐ. The l_{b} part from the output terminal to the ground terminal of coplanar waveguide is retained and also divided into l_{b1} and l_{b2} by two parallel Josephson junctions J_{b}. Two sets of Josephson junctions, Jₐ and J_{b}, adjust the local magnetic field by biasing DC1 and DC2 with DC current, respectively.

The difference between FIG. 3 and FIG. 4 is whether there is a separate part l_{b} from the output end to the ground end of the coplanar waveguide. If any, another Josephson junctions are provided from the output end to the ground end. If no, Josephson junctions are provided at the output end.

FIG. 5 is an equivalent circuit diagram of a quantum chip provided in an embodiment of the disclosure. Referring to FIG. 5, the filter's coplanar waveguide part can be represented as the equivalent capacitance C_{f} and equivalent inductance L_{f} in the virtual box. The capacitances C₁ᵣ to Cₙᵣ are the coupling capacitances between the resonant cavities and the filter corresponding to n different qubits. C₁₂ to Cₙ₂ are the coupling capacitance between n different qubits and their corresponding resonant cavities. These resonant cavities corresponding to different qubits share the same filter. Cₙ₁ and Lₙ₁ parallel structures represent resonant cavities. Cₙ₃ and Jₙ₁ parallel structures represent qubits.

The above description shows the length from the input end to the output end of the filter, and the center frequency range and bandwidth range of the filter. In addition, the area of the Josephson junctions also affects the center frequency range and bandwidth range of the filter. Its specific parameters need to be determined during the quantum chip design phase.

In some embodiments, in step S11, determine the center frequency range and bandwidth range of the corresponding filter based on multiple resonant cavities coupled to the readout line. Determine a large center frequency range and bandwidth range based on the parameters of the resonant cavities that needs to be used to ensure that the filter can cover these resonant cavities.

Josephson junctions, also known as superconducting tunnel junction and, generally, is a structure composed of two superconductors sandwiched by a very thin barrier layer (thickness≤coherence length of Cooper electron pair). Examples include the S-I (semiconductor or insulator)-S (superconductor) structure, abbreviated as SIS. The critical current of Josephson junctions is determined by its area, and the larger the area, the higher the critical current value. Josephson junctions can be equivalent to an inductor in a circuit. The equivalent inductances of Josephson junctions can be obtained using the equation of the Josephson junctions.

In Step S12, preset an initial length and initial inductance set from input to output. The initial inductance set is a set of equivalent inductances of the pre-set Josephson junctions. The area of the Josephson junctions can be calculated in reverse based on the inductance value.

The Josephson junctions are disposed on a coplanar waveguide. Two parallel Josephson junctions are grounded. The frequency and bandwidth of the filter can be regulated by adjusting the position of the Josephson junctions in the coplanar waveguide and the DC bias near the junction. A single or multiple Josephson junctions are floating grounded, that is, directly connected in series in the center conductor of a coplanar waveguide. It can not only reduce the size of the filter, but achieve the same effect.

In Step S13, determine whether there are inductance values in the initial inductance set that meet both the center frequency range and the bandwidth range, based on the initial length. Simulate whether any combination of conditions meets the conditions one by one, or to first filter a class of parameters that meet the conditions and then filter parameters that meet another condition.

If there are no parameters that meet the conditions, adjust the initial length. Until there are inductance values in the initial inductance set that meet both the center frequency range and the bandwidth range.

Determine the area of the Josephson junctions based on the selected inductance set. Determine the length from the input end to the output end of the coplanar waveguide based on the current initial length, in order to determine the design parameters of quantum chips.

In actual chip processing, there can be an overall offset of the filter between the center frequency and the resonant cavity frequency. Due to the fact that the center frequency of a typical bandpass filter is not adjustable, this offset cannot be corrected after processing. For filters with adjustable inductance that are added with Josephson junctions, the filter's center frequency can be adjusted by DC current bias, thereby correcting the frequency offset and achieving better filtering effect. This can alleviate the pressure of overall frequency offset in filter parameter design and provide greater fault-tolerant space for chip fabrication. And the Josephson junctions on the filter can be prepared together with the Josephson junctions on the qubit. So it does not increase the process complexity, and merely simple adjustments can be made for the layout.

Based on the quantum chip parameter determination method provided in the disclosure, the quantum chip includes: a filter. The filter includes a coplanar waveguide, at least one pair of parallel Josephson junctions, and an input coupling capacitor. The coplanar waveguide is coupled to the readout line. The Josephson junctions are disposed on a coplanar waveguide. The input coupling capacitor is disposed at the input end of coplanar waveguide. Determine the center frequency range and bandwidth range of the corresponding to filtering based on multiple resonant cavities coupled to the readout line. Acquire the initial length from the input end to the output end of coplanar waveguide. The initial inductance set is a set of preset equivalent inductances of the Josephson junctions. Determine whether there are inductance values in the initial inductance set that meet both the center frequency range and the bandwidth range, based on the initial length. If any, output the selected inductance set. If no, adjust the initial length until there are inductance values in the initial inductance set that meet both the center frequency range and the bandwidth range. Determine the area of the Josephson junctions based on the selected inductance set. Determine the length from the input end to the output end of the coplanar waveguide based on the current initial length. Josephson junctions are provided on the coplanar waveguide of the filter provided in the disclosure. Adjusting the critical current of the Josephson junctions and changing the equivalent inductances corresponding to the filter enables regulating the center frequency of the filter. The initial length that meets the center frequency range and bandwidth range, as well as the inductance set are selected. So that the Josephson junctions can, during regulation, cover the frequencies required by all resonant cavities, encompassing all resonant cavity frequency bands through one filter. During use, the bandwidth and center frequency of the filter can be regulated by adjusting the critical current of the Josephson junctions to achieve better filtering effect.

Based on the above embodiment, the embodiment provides a specific screening scheme. Determining whether there are inductance values in the initial inductance set that meet both the center frequency range and the bandwidth range based on the initial length includes:
determine whether there are inductance values in the initial inductance set that meet the center frequency range based on the initial length;
if any, acquire the corresponding filtering bandwidth data set based on the inductance value set that meets the center frequency range;
determine whether the filtering bandwidth data set meets the bandwidth range;
if meeting, it is determined that there are inductance values in the initial inductance set that meet both the center frequency range and the bandwidth range;
if no or not meeting, it is determined that there are no inductance values in the initial inductance set that meet both the center frequency range and the bandwidth range.

In some embodiments, first determine whether there are inductance values in the initial inductance set that meet the center frequency range based on the initial length. After filtering out the inductance values that meet the conditions, confirm the corresponding filtering bandwidth range for each inductance value. Determine whether each filtering bandwidth data set meets the bandwidth range. That is, determine whether the bandwidth range is included in the bandwidth range of the filtering bandwidth data set. Filter out the inductance values that meet the bandwidth range. If there is no inductance value that meets the center frequency range or the inductance value does not meet the bandwidth range, the initial length needs to be adjusted for judgment again.

Based on the inductance set of a set of Josephson junction inductances, determine that the area of the Josephson junctions is related to the process details of the Josephson junctions. It is necessary to ensure that the internal magnetic field corresponding to the designed Josephson junction area S is adjustable. The adjustment range of the parallel grounded double junction equivalent inductances can cover this set of inductance values. Due to the fact that the frequency of resonant cavities is usually set between 6-7 GHz. The equivalent inductances of the filter at the junction only occupies a limited width, this condition can usually be met.

The quality factor formula of the filter can be referred to for the correction of bandwidth offset. As lₐ increases, l_{b} decreases, the filter's quality factor increases, and the filter's bandwidth narrows. Therefore, a filter's bandwidth is negatively correlated with lₐ and varies monotonically. Selecting a set of lₐ for simulation can roughly help determine the quantitative relationship between lₐ and filter bandwidth.

Specifically, calculating the filtering quality factor for each inductance value helps acquire the corresponding filtering bandwidth. Acquiring the corresponding filtering bandwidth data set based on the inductance value set that meets the center frequency range includes:
acquiring the corresponding filtering quality factor data set based on the inductance value set that meets the center frequency range; and
acquiring the corresponding filtering bandwidth data set based on the filtering quality factor data set.

Based on the above embodiment, and in a specific embodiment, the coplanar waveguide includes a first coplanar waveguide segment and a second coplanar waveguide segment;
the first coplanar waveguide segment is a segment from the input end to the output end of the coplanar waveguide; the second coplanar waveguide segment is a segment from the output end to the ground end of the coplanar waveguide;
the Josephson junctions are disposed at the intersection of the first coplanar waveguide segment and the second coplanar waveguide segment.
The Josephson junctions are disposed at the intersection of the first coplanar waveguide segment and the second coplanar waveguide segment. Two coplanar waveguides are regulated through a pair of Josephson junctions.

If the filter is based on a λ/2 wavelength resonant cavity, an output coupling capacitor needs to be added to the right side of the coplanar waveguide of the filter. Specifically, the filter further includes an output coupling capacitor; and
the output coupling capacitor is disposed at the output end of the readout line.

Based on the above embodiment, the center frequency and bandwidth of the filter can be adjusted by regulating the position, area, and DC bias current of the Josephson junctions in the filter. The first two parameters are determined during the filter design phase, so as to determine the center frequency range and bandwidth range of the filter. The DC bias current, which is determined during the filter usage phase, can be used to adjust the filter's center frequency. The embodiment provides a filtering regulation method for quantum chip, applied to the quantum chips prepared based on the aforementioned quantum chip parameter determination method;

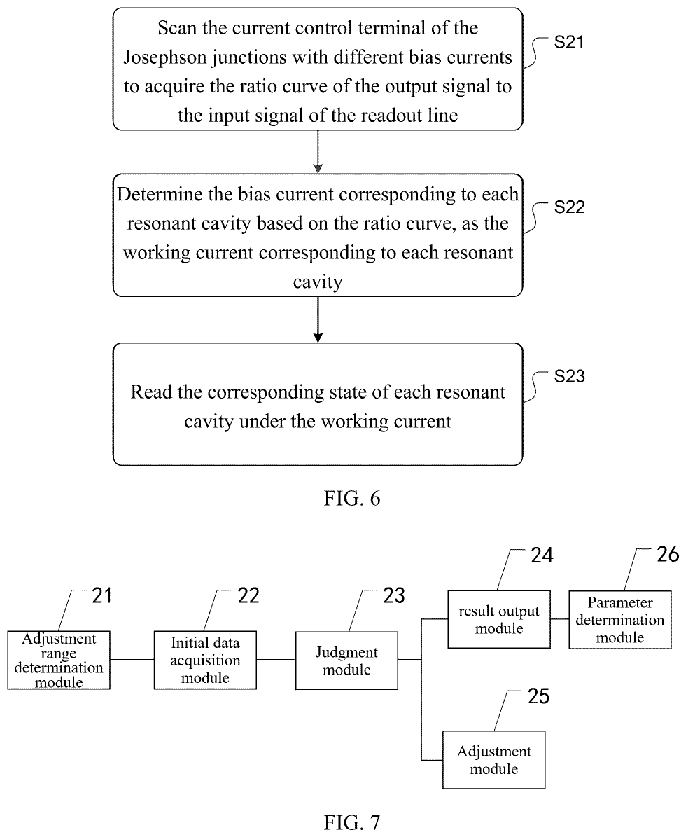

Referring to FIG. 6, the method includes:
S21: scanning the current control terminal of the Josephson junctions with different bias currents to acquire the ratio curve of the output signal to the input signal of the readout line;
S22: determining a bias current corresponding to each resonant cavity based on the ratio curve, as the working current corresponding to each resonant cavity; and
S23: reading the corresponding state of each resonant cavity under the working current.

After the preparation of quantum chips, the embodiment provides a filtering frequency regulation method during use. By scanning the current control terminal of the Josephson junctions with different bias currents, the ratio curve of the output signal to the input signal of readout line is obtained. In quantum computing, the interaction between qubits is controlled by microwave signals. In order to achieve efficient quantum computing, it is necessary to ensure that the frequency of microwave signal matches the center frequency of qubit. Measuring the ratio between the output microwave signal and the input microwave signal can help determine the frequency of microwave signal. Thus, obtain the intrinsic frequency of the resonant cavity corresponding to each qubit.

Based on the ratio curve, therefore, the bias current corresponding to each resonant cavity can be determined as the working current for the subsequent resonant cavity. If it is necessary to read a certain resonant cavity, the state of each corresponding resonant cavity can be read under the working current. Conducting a detailed measurement can help define the corresponding relationship between the working currents of each resonant cavity. For subsequent use, it is simply required to query the available working current values. Set the filter's center frequency separately for each resonant cavity corresponding to each qubit. Thus improving the filtering efficiency without losing the frequency range that can be selected.

The filtering regulation method for quantum chips provided in the disclosure is applied to the quantum chips prepared based on the aforementioned quantum chip parameter determination method. Scan the current control terminal of the Josephson junctions with different bias currents to acquire the ratio curve of the output signal to the input signal of the readout line. Determine a bias current corresponding to each resonant cavity based on the ratio curve, as the working current corresponding to each resonant cavity. Read the corresponding state of each resonant cavity under the working current. The working current of each resonant cavity is obtained by scanning. When reading is required, the working current of the Josephson junctions is adjusted to enable the filter operate at the corresponding center frequency and bandwidth range. Since the filter's center frequency is adjustable, the filter can be designed with a narrow bandwidth to improve the filtering effect, while not losing the frequency range of filtering. And multiple resonant cavities share one filter, significantly saving the space required by the filtering circuit. So that the filter can be integrated on a quantum chip having a large number of qubits.

Based on the above embodiment, specifically, scanning the current control terminal of the Josephson junctions with different bias currents to acquire the ratio curve of the output signal to the input signal of the readout line includes:

Scan the current control terminal of the Josephson junctions with a bias current at a first preset current interval. Acquire a first curve of the output signal and input signal of the readout line.

Determine the target center frequency and bandwidth of each resonant cavity, that is, the corresponding current bias range, based on the first curve.

Scan the current control terminal of the Josephson junctions within the current bias range with a bias current at a second preset current interval. Acquire a second curve of the output signal and input signal of the readout line.

Take the second curve as the ratio curve.

In some embodiments, the ratio curve is determined through two scans. The current control terminal of the Josephson junctions is scanned through the bias current of the first preset current interval to acquire the first curve of the output signal and input signal of the readout line. The purpose is to roughly find the frequency of all resonant cavities. Conduct further analysis in detail, within the current bias range corresponding to each resonant cavity. Scan the current control terminal of the Josephson junctions with a bias current at a second preset current interval to acquire the second curve of the output signal and input signal of the readout line. Naturally, the second preset current interval is smaller than the first preset current interval. Measuring the second curve at smaller current intervals can help determine the specific values of the operating current corresponding to the target center frequency and bandwidth of each resonant cavity.

In addition, scanning the current control terminal of the Josephson junctions with a bias current at a first preset current interval includes:
scanning the current control terminal of the Josephson junctions with a bias current at a first preset current interval during an oscillation period of the Josephson junctions.

The equivalent inductances of the Josephson junctions vary periodically with the bias of the DC current. So the scanning current only needs to change within one oscillation cycle.

In the above embodiments, a quantum chip parameter determination method is described in detail. The disclosure also provides corresponding embodiments of the quantum chip parameter determination device. It should be noted that the disclosure describes the embodiments of the device part from the perspective of functional modules.

From the perspective of functional modules, the present embodiment provides a structural diagram of a quantum chip parameter determination device. The quantum chip includes: a filter. The filter includes a coplanar waveguide, at least one pair of parallel Josephson junctions, and an input coupling capacitor. The coplanar waveguide is coupled to the readout line. The Josephson junctions are disposed on a coplanar waveguide. The input coupling capacitor is disposed at the input end of coplanar waveguide.

FIG. 7 is a structural diagram of a quantum chip parameter determination device provided in an embodiment of the disclosure. Referring to FIG. 7, the device includes:
an adjustment range determination module 21 that is used to determine the center frequency range and bandwidth range of the corresponding to filtering based on multiple resonant cavities coupled to the readout line;
an initial data acquisition module 22 that is used to acquire the initial length from the input end to the output end of the coplanar waveguide. The initial inductance set is a set of preset equivalent inductances of the Josephson junctions;
a judgment module 23 that is used to determine whether there are inductance values in the initial inductance set that meet both the center frequency range and the bandwidth range based on the initial length. If any, trigger a result output module. If no, trigger an adjustment module;
a result output module 24 that is used to output the selected inductance set;
an adjustment module 25 that is used to adjust the initial length until there are inductance values in the initial inductance set that meet both the center frequency range and the bandwidth range; and
a parameter determination module 26 that is used to determine the area of the Josephson junctions based on the selected inductance set. Determine the length from the input end to the output end of the coplanar waveguide based on the current initial length.

In the quantum chip parameter determination device provided in the embodiments of the disclosure, the Josephson junctions are provided on the coplanar waveguide of the filter. Adjust the critical current of the Josephson junctions and change the equivalent inductances corresponding to the filter enables regulating the center frequency of the filter. The initial length that meets the center frequency range and bandwidth range, as well as the inductance set are selected. So that the Josephson junctions can, during regulation, cover the frequencies required by all resonant cavities, encompassing all resonant cavity frequency bands through one filter and during use. The bandwidth and center frequency of the filter can be regulated by adjusting the critical current of the Josephson junctions to achieve better filtering effect.

The quantum chip filtering regulation method is described in detail in the above embodiments, and the disclosure also provides corresponding embodiments of the quantum chip filtering regulation device. It should be noted that the disclosure describes the embodiments of the device part from the perspective of functional modules.

From the perspective of functional modules, the present embodiment provides a structural diagram of a quantum chip filtering regulation device,

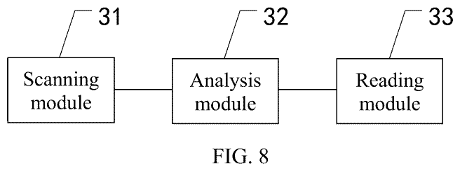

FIG. 8 is a structural diagram of a quantum chip filtering regulation device provided in an embodiment of the disclosure. Referring to FIG. 8, the device includes:
a scanning module 31 that is used to scan the current control terminal of the Josephson junctions with different bias currents to acquire the ratio curve of the output signal to the input signal of the readout line
an analysis module 32 that is used to determine the bias current corresponding to each resonant cavity based on the ratio curve, as the working current corresponding to each resonant cavity; and
a reading module 33 that is used to read the state of each corresponding resonant cavity under the working current.

In some embodiments, the working current of each resonant cavity is obtained by scanning. When reading is required, the working current of the Josephson junctions is adjusted +ble the filter operate at the corresponding center frequency and bandwidth range. Since the filter's center frequency is adjustable, the filter can be designed with a narrow bandwidth to improve the filtering effect, while not losing the frequency range of filtering. And multiple resonant cavities share one filter, significantly saving the space required by the filtering circuit. So that the filter can be integrated on a quantum chip having a large number of qubits.

The quantum chip parameter determination method and device, filtering regulation method and device provided in the disclosure is introduced in detail above. The various embodiments in the specification are described in a progressive manner. The differences from other embodiments are emphasized in detail in each embodiment. The same and similar parts between the embodiments can be referred to each other. The device disclosed in the embodiments is described in a relatively simple manner as it corresponds to the method disclosed in the embodiments. Referring to the method part for relevant information. It should be noted that the person having ordinary skill in the art can make several improvements and modifications to the disclosure without departing from the principles of the disclosure. And these improvements and modifications also fall within the scope of protection of the claims of the disclosure.

It should also be noted that relationship terms in the specification, such as first and second, are only used to distinguish one entity or operation from another. It does not necessarily require or imply any such actual relationship or order between these entities or operations. Moreover, the terms ‘including’, ‘comprising’, or any other variation thereof are intended to encompass non-exclusive inclusion. Therefore, a process, method, item, or device that includes a series of elements, not only includes those elements, but also other elements not explicitly listed, or elements inherent to such process, method, item, or device. Without further limitations, the element defined by the statement ‘including . . . ’ does not exclude the existence of other identical elements in the process, method, item, or device that includes the element in question.

What is claimed is:

1. A quantum chip parameter determination method, wherein the quantum chip comprises: a filter; the filter comprises a coplanar waveguide, at least one pair of parallel Josephson junctions, and an input coupling capacitor; wherein the coplanar waveguide is coupled to a readout line; the Josephson junctions are disposed on the coplanar waveguide; the input coupling capacitor is disposed at an input end of the coplanar waveguide;
the method comprises:
determining a center frequency range and a bandwidth range corresponding to filtering based on a plurality of resonant cavities coupled to the readout line;
acquiring an initial length from the input end to an output end of the coplanar waveguide, and an initial inductance set which is a set of preset equivalent inductances of the Josephson junctions;
determining whether there are inductance values in the initial inductance set that meet both the center frequency range and the bandwidth range, based on the initial length;
if any, outputting a selected inductance set;
if no, adjusting the initial length until there are inductance values in the initial inductance set that meet both the center frequency range and the bandwidth range; and
determining an area of the Josephson junctions based on the selected inductance set, and determining the length from the input end to the output end of the coplanar waveguide based on the current initial length.

2. The method of claim 1, wherein determining whether there are inductance values in the initial inductance set that meet both the center frequency range and the bandwidth range based on the initial length comprises:
determining whether there are inductance values in the initial inductance set that meet the center frequency range based on the initial length;
if any, acquiring a corresponding filtering bandwidth data set based on the inductance value set that meets the center frequency range;
determining whether the filtering bandwidth data set meets the bandwidth range;
if meeting, it is determined that there are inductance values in the initial inductance set that meet both the center frequency range and the bandwidth range;
if no or not meeting, it is determined that there are no inductance values in the initial inductance set that meet both the center frequency range and the bandwidth range.

3. The quantum chip parameter determination method of claim 2, wherein acquiring the corresponding filtering bandwidth data set based on the inductance value set that meets the center frequency range comprises:
acquiring a corresponding filtering quality factor data set based on the inductance value set that meets the center frequency range; and
acquiring the corresponding filtering bandwidth data set based on the filtering quality factor data set.

4. The quantum chip parameter determination method of claim 1, wherein the coplanar waveguide comprises a first coplanar waveguide segment and a second coplanar waveguide segment;
wherein the first coplanar waveguide segment is a segment from the input end to the output end of the coplanar waveguide; the second coplanar waveguide segment is a segment from the output end to a ground end of the coplanar waveguide;
the Josephson junctions are disposed at the intersection of the first coplanar waveguide segment and the second coplanar waveguide segment.

5. The quantum chip parameter determination method of claim 4, wherein the filter further comprises an output coupling capacitor;
the output coupling capacitor is disposed at an output end of the readout line.

6. A filtering regulation method for quantum chip, applied to the quantum chip prepared based on the quantum chip parameter determination method of claim 1;
the method comprises:
scanning a current control terminal of Josephson junctions with different bias currents to acquire a ratio curve of an output signal to an input signal of a readout line;
determining the bias current corresponding to each resonant cavity based on the ratio curve, as a working current corresponding to each resonant cavity; and
reading a corresponding state of each resonant cavity under the working current.

7. The filtering regulation method for quantum chip of claim 6, wherein scanning the current control terminal of the Josephson junctions with different bias currents to acquire the ratio curve of the output signal to the input signal of the readout line comprises:
scanning the current control terminal of the Josephson junctions with a bias current at a first preset current interval, acquiring a first curve of the output signal and input signal of the readout line;
determining a target center frequency and bandwidth of each resonant cavity, that is, a corresponding current bias range, based on the first curve;
scanning the current control terminal of the Josephson junctions within the current bias range with a bias current at a second preset current interval, acquiring a second curve of the output signal and input signal of the readout line; and
taking the second curve as the ratio curve.

8. The filtering regulation method for quantum chip of claim 7, wherein scanning the current control terminal of the Josephson junctions with the bias current at the first preset current interval comprises:
scanning the current control terminal of the Josephson junctions with the bias current at the first preset current interval during an oscillation period of the Josephson junctions.

9. A quantum chip parameter determination device, wherein the quantum chip comprises: a filter; the filter comprises a coplanar waveguide, at least one pair of parallel Josephson junctions, and an input coupling capacitor; wherein the coplanar waveguide is coupled to a readout line; the Josephson junctions are disposed on the coplanar waveguide; the input coupling capacitor is disposed at an input end of the coplanar waveguide;
the device comprises:
an adjustment range determination module that is used to determine a center frequency range and a bandwidth range of the corresponding to filtering based on a plurality of resonant cavities coupled to the readout line;
an initial data acquisition module that is used to acquire an initial length from the input end to an output end of the coplanar waveguide, and an initial inductance set which is a set of preset equivalent inductances of the Josephson junctions;
a judgment module that is used to determine whether there are inductance values in the initial inductance set that meet both the center frequency range and the bandwidth range based on the initial length; if any, trigger a result output module; if no, trigger an adjustment module;
the result output module is used to output a selected inductance set;
the adjustment module is used to adjust the initial length until there are inductance values in the initial inductance set that meet both the center frequency range and the bandwidth range; and
a parameter determination module that is used to determine an area of the Josephson junctions based on the selected inductance set, and determine the length from the input end to the output end of the coplanar waveguide based on the current initial length.
